(19) United States
(12) Patent Application Publication
(10) Pub. No.: US 2010/0068832 A1
(43) Pub. Date: Mar. 18, 2010

(54) METHOD FOR THE PROTECTION OF INFORMATION IN MULTI-PROJECT WAFERS

(76) Inventor: Hui-Shen Shih, Chang-Hua Hsien (TW)

Correspondence Address: NORTH AMERICA INTELLECTUAL PROPERTY CORPORATION, P.O. BOX 506, MERRIFIELD, VA, 22116, US

(21) Appl. No.: 12/211,071

(22) Filed: Sep. 15, 2008

(51) Int. Cl. H01L 21/66

(52) U.S. Cl. 438/16; 257/E21.53

(57) ABSTRACT

A method for the protection of the information in a multi-project wafer (MPW) is provided. First, a substrate is provided. There are a first die and a second die on the substrate. Second, a first wafer process is performed on the substrate. The first wafer process includes performing a wafer procedure by using a non-destructive energy source and destroying the first die by using a destructive energy source. Later, a second wafer process is performed to finish the second die.

### BACKGROUND OF THE INVENTION

1. Field of the Invention

The present invention relates to a method for the protection of the information in a multi-project wafer (MPW). In particular, the present invention relates to a method for the protection of the information in a multi-project wafer (MPW) by using a destructive energy source.

2. Description of the Prior Art

In the current semiconductor process, many processing procedures, such as deposition, lithography, etching and ion implantation are used to manufacture wafers so as to further manufacture chips which are integrated in many electronic devices and play different roles. For example, in the lithographic step, reticles are employed to precisely transfer the determined layout patterns one by one onto the wafers. For different lithographic steps, specific reticles are fabricated in order to correspond to different layout patterns.

With the advancing technology of the semiconductor process and the decreasing critical dimension of elements, the fabrication of the reticles is more and more difficult and more and more complicated. For example, optical proximity correction is required to correct the photo resist patterns after the lithographic exposure. Such more and more complicated fabrication process makes the cost of the reticles higher and higher. The manufacturers of chips frequently carry out test production of the chips for different projects which are still in the experimental design stage. According to different sizes of wafers, a single wafer may obtain chips up to thousands, more than the number required. Once the design is found flawed, maybe all of the chips, including the very expensive reticles, are cast off. In addition, in most cases, a successful chip design may require at least two test runs. As a result, the production of small amount test chips becomes a heavy burden of the manufacturers of chips both financially and administratively. Especially for the smaller chip manufacturers, it is even more risky to face the problem alone.

Since the late 1970s, the multi-project wafer (MPW) has gradually developed. The multi-project wafer (MPW) is a whole new idea, which allows pattern designs of different layouts to be merged in the same reticle and sharing the same manufacturing process to lower the cost of each chip.

It is well recognized that the multi-project wafer (MPW) is both economical and efficient. This is especially important for the smaller companies which hold key technologies or for designers who need only small amount of chips to be fabricated. When the cost for reticles becomes higher and higher, it is very important for them to find an alternative way to lower the cost, since they can share the expensive cost to fabricate the reticles together.

For example, corporation centers now are available to recruit the candidates of chip manufacturers who wish to join the business and to charge them the reasonable, split fee in order to provide the service of the multi-project wafer (MPW), which enables the idea to make the chip manufacturers split the fee to fabricate the same reticle. The multi-project wafer (MPW) allows different designs placed on the same reticle and sharing the same manufacturing process to lower the cost of each chip. Such idea is similar to the “car pool” system. It creates a win-win result to all of the participants.

In spite of the great advantage of the multi-project wafer (MPW) for the chip manufacturers to split the high cost for fabricating the wafer in order to lower the cost, there still exists a potential issue for all of the chip manufacturers, that is, revealing their business secrets. A current solution to keep the business secrets from being revealed is to cut the wafer into chips and to make sure only the correct chips are delivered to each of the correct clients. In such way, though the secret is safe with the client, it may not meet the client's demands.

Besides, one of the current fashions to cut the wafer into chips of different sizes is by diamond saws. However, such conventional method usually makes the crack propagate along all the direction on the kerf. The crack damages the layout structure and makes the chip failed.

For example, U.S. patent application 2007/0264798 discloses a method and a system for partially removing circuit patterns from a multi-project wafer. This method and this system can be used to provide a multi-project-wafer to a user without disclosing proprietary circuit information of other customers. At least one integrated circuit design of a user is identified from a plurality of integrated circuit designs of a plurality of users. Those unidentified circuits can be totally removed through a circuit removing method. Then the modified multi-project wafer can be delivered to the user without concerns about disclosing information of unidentified circuits which belong to other customers. In one embodiment, a laser system may be used to totally remove the unidentified integrated circuit designs before being delivered to the specific customer without impacting the circuit performance of identified circuits. In another embodiment, a diamond-blade saw may also be used to totally remove the unidentified integrated circuit designs before being delivered to the specific customer without impacting the circuit performance of identified circuits. Because such method and system for partially removing circuit patterns from a multi-project wafer are to additionally add steps in the conventional semiconductor process to totally remove the unidentified integrated circuit designs, such method and system for partially removing circuit patterns from a multi-project wafer are basically not compatible with the conventional semiconductor process. Besides, when a diamond-blade saw is used to totally remove the unidentified integrated circuit designs, the crack would propagate along all the direction on the kerf. The crack may likely damage the layout structure and make the chip failed.

Therefore, there is a need for a novel method compatible with the conventional semiconductor process to protect the information in the multi-project wafer (MPW) from the irrelevant third party.

### SUMMARY OF THE INVENTION

The present invention is directed to a method to protect the information in the multi-project wafer (MPW). The method of the present invention employs a destructive energy source which is compatible with the conventional semiconductor process, such as those used in the laser marking procedure for the substrate during the wafer process, to destroy the irrelevant business secrets in the wafer in stead of a traditional diamond-blade saw. In such way, the novel method would not waste any useful chips and also simultaneously destroys the irrelevant business secrets in the wafer by a simple and convenient way to protect the information in the multi-project wafer (MPW) from the irrelevant third party.

The present invention first provides a method for the protection of the information in a multi-project wafer (MPW). In the beginning, a substrate is provided. There are a first die and a second die on the substrate. Second, a first wafer process is performed on the substrate. The first wafer process includes performing a wafer procedure by using a non-destructive energy source and destroying the first die by using a destructive energy source. Later, a second wafer process is performed to finish the second die.

The present invention again provides a method for the protection of the information in a multi-project wafer (MPW). In the beginning, a substrate is provided. There are a first die and a second die on the substrate. Second, a first wafer process is performed on the substrate. Later, an apparatus is used to perform a wafer procedure process and a die destruction process. Then, a second wafer process is performed to finish the second die.

The present invention further provides a method for the protection of the information in a multi-project wafer (MPW). In the beginning, a substrate is provided. There are a first die and a second die on the substrate. Second, a first wafer process is performed on the substrate. The first wafer process includes performing a wafer procedure by using a non-destructive energy source and destroying part of the first die by using a destructive energy source.

In the method to protect the information in the multi-project wafer (MPW) of the present invention, a destructive energy source is simultaneously employed to destroy the irrelevant business secrets in the die while a non-destructive energy source is used in a wafer procedure. In such way, the novel method would not waste any useful chips and destroy the irrelevant business secrets in the dies at the same time by a procedure compatible with the conventional semiconductor process to protect the information in the multi-project wafer (MPW) from the irrelevant third party.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a preferred embodiment of the method to protect the information in the multi-project wafer (MPW).

FIGS. 5-8 illustrate a preferred embodiment of another method to protect the information in the multi-project wafer (MPW).

### DETAILED DESCRIPTION

The present invention is directed to a method to protect the information in the multi-project wafer (MPW). The method of the present invention which is compatible with the conventional semiconductor process employs a destructive energy source, such as those used in the laser marking procedure for the substrate during the wafer process, to destroy the irrelevant business secrets in the wafer in stead of a diamond-blade saw. In such way, the novel method would not waste any useful chips and simultaneously destroys the irrelevant business secrets in the wafer by a simple and convenient way to protect the information in the multi-project wafer (MPW) from the irrelevant third party.

FIGS. 1-4 illustrate a preferred embodiment of the method to protect the information in the multi-project wafer (MPW). As shown in FIG. 1, a substrate 10 is provided. The substrate 10 includes multiple shots 100. Each shot 100 may include at least a first die 110 and a second die 120. Please note that the first die 110 and the second die 120 are for illustration only. In other words, each shot 100 on the substrate 10 may further include a third die 130 and a forth die 140. Different dies may be provided by different entities, users, producers or manufacturers and each shot 100 includes multiple, array-like die regions. The multiple dies in each shot 100 may belong to different clients, such as two clients, three clients or four clients. Different dies are different in many aspects. The following descriptions are merely directed to the first die 110 and the second die 120.

The substrate 10 may be a regular semiconductor wafer, such as a multi-project wafer (MPW) to fabricate different chips for different clients. Different chip manufacturers join the multi-project wafer (MPW) to fabricate chips of different applications or functions in the same wafer. Suppose a first chip manufacturer and a second chip manufacturer respectively join the same multi-project wafer (MPW) and the same multi-project wafer (MPW) is used to fabricate the first chip 110 and a second chip 120 of different applications or functions. Both the first chip manufacturer and the second chip manufacturer do not wish their business secrets to be revealed to each other or to another irrelevant third party.

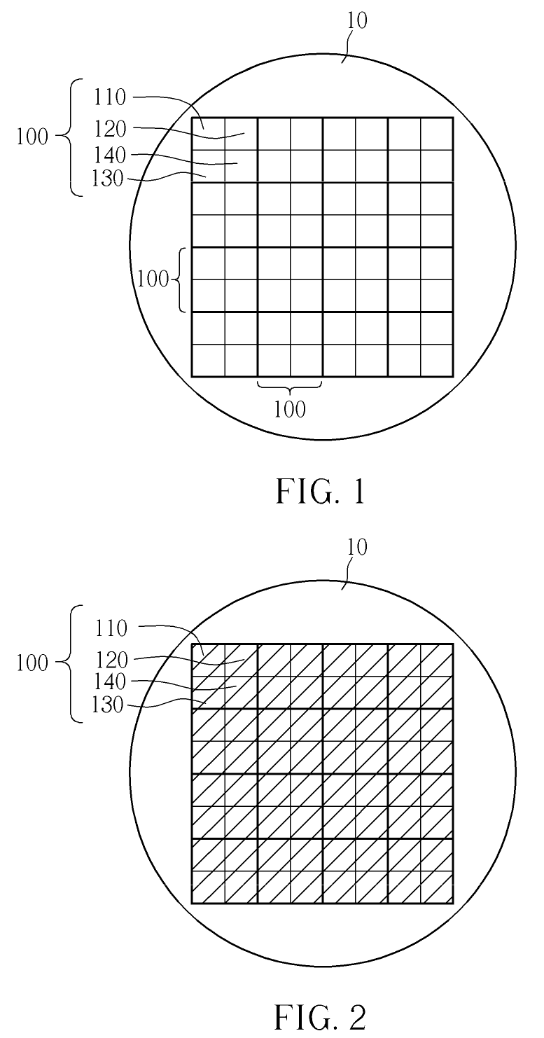

During the fabrication of the substrate 10, as shown in FIG. 2, a first wafer process is performed on the substrate 10. Before the first wafer process, the substrate 10 may have already undergone other wafer process(es) in advance, such as laser marking, ion implantation, deposition, lithography or etching . . . etc. to construct a preliminary doped regions, element allocation or layout patterns. Accordingly, in the first wafer process, a non-destructive energy source may be employed to carry out a thickness measurement or a defect review by laser, incoherent light and/or electron beams.

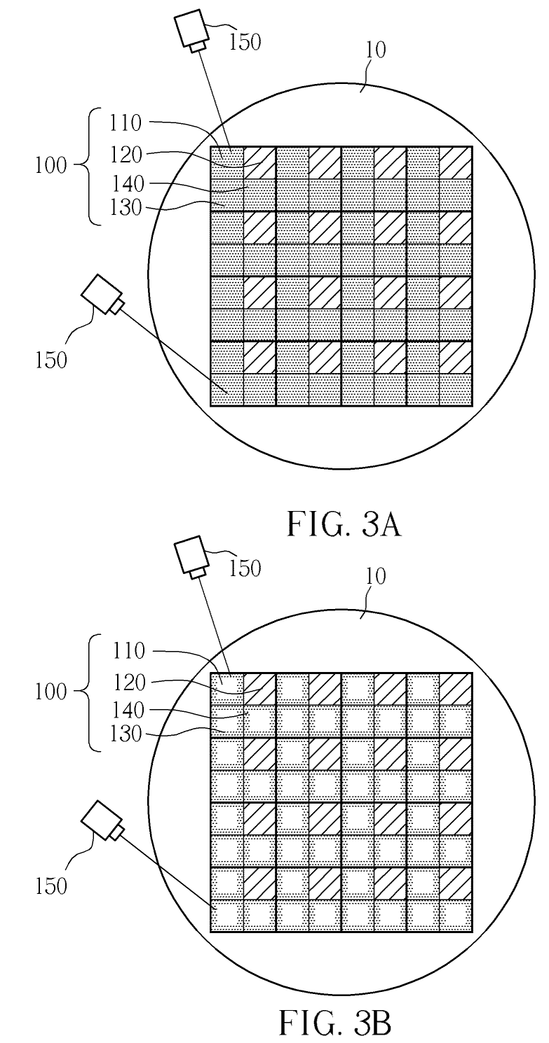

Before, during or after the first wafer process, the method for the protection of the information in a multi-project wafer (MPW) of the present invention again employs a destructive energy source 150 to totally destroy the information which is irrelevant to the first chip manufacturer or the second chip manufacturer optionally, as shown in FIGS. 3A/3B. For example, if the substrate 10, i.e. the wafer, is delivered to the second chip manufacturer, the business secrets which are irrelevant to the second chip manufacturer are required to be destroyed, for instance to completely destroy the dies other than the second die 120, as shown in FIG. 3A, or to destroy part of the dies other than the second die 120, such as the bonding pad and /or the test key pad, as shown in FIG. 3B.

Or, more specifically speaking, part or entire of the first die region 110, the third die region 130 and the forth die region 140 may be completely destroyed. Laser, X ray, electron beams and the combination thereof may be used as the destructive energy source. Because the destructive energy source has extremely high energy and is capable of completely destroying all of the irrelevant, secret information in the wafer, the information in the die in the multi-project wafer (MPW) is protected from the irrelevant third party.

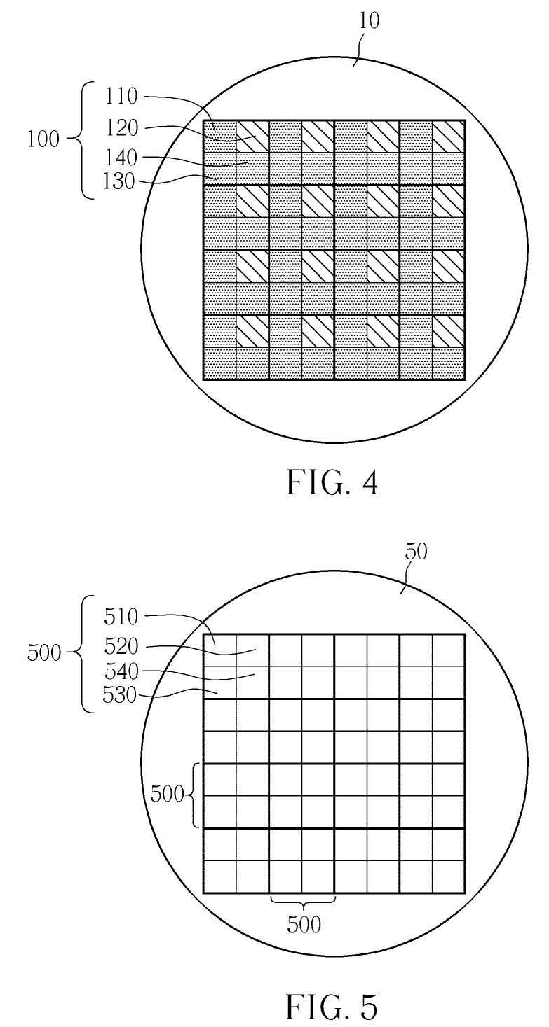

After irrelevant information is completely destroyed in the wafer by the destructive energy source 150, as shown in FIG. 4, a second wafer process is then performed on the substrate 10 to finish the dies. The second wafer process may be various conventional semiconductor processes, or similar to these semiconductor processes which the substrate 10 undergoes before the first wafer process, such as a lithographic procedure, a deposition procedure, an etching procedure, a cleaning procedure and a CMP procedure or the combination thereof. After the second wafer process, only the final products of the second die 120 remain on the substrate 10. Now, the entire wafer is ready to be delivered to the second chip manufacturer without worrying about the secret information being revealed to other chip manufacturers, for example the first dies 110 of the first chip manufacturer.

On the other hand, if the entire wafer is delivered to the first chip manufacturer, please refer to the previous descriptions, the other irrelevant business secrets in the die(s) need to be completely destroyed, for instance to partially destroy the second die 120, the third die 130 and the forth die 140 or the entire die and to keep the first die 110. In such way, only the final products of the first die 110 still remain on the substrate 10. Now, the entire wafer is ready to be delivered to the first chip manufacturer without worrying about the secret information being revealed to other chip manufacturers.

The present invention again provides a method for the protection of the information in a multi-project wafer (MPW). FIGS. 5-8 illustrate a preferred embodiment of another method to protect the information in the multi-project wafer (MPW). In the beginning, as shown in FIG. 5, a substrate 50 is provided. The substrate 50 includes multiple shots 500. Each shot 500 may include at least a first die 510 and a second die 520. Please note that the first die 510 and the second die 520 are for illustration only. In other words, each shot 500 on the substrate 50 may further include a third die 530 and a forth die 540. Similarly, different dies may be provided by different entities, users, producers or manufacturers and each shot 500 includes multiple, array-like die regions. The multiple dies in each shot 500 may belong to different clients, such as two clients, three clients or four clients. The following descriptions are merely directed to the first die 510 and the second die 520.

The substrate 50 may be a regular semiconductor wafer, such as a multi-project wafer (MPW) to fabricate different chips for different clients. Different chip manufacturers join the multi-project wafer (MPW) to fabricate chips of different applications or functions in the same wafer. Suppose a first chip manufacturer and a second chip manufacturer respectively join the same multi-project wafer (MPW) and the same multi-project wafer (MPW) is used to fabricate the first chip 510 and a second chip 520 of different applications or functions. Both the first chip manufacturer and the second chip manufacturer do not wish their business secrets to be revealed to each other or to another irrelevant third party.

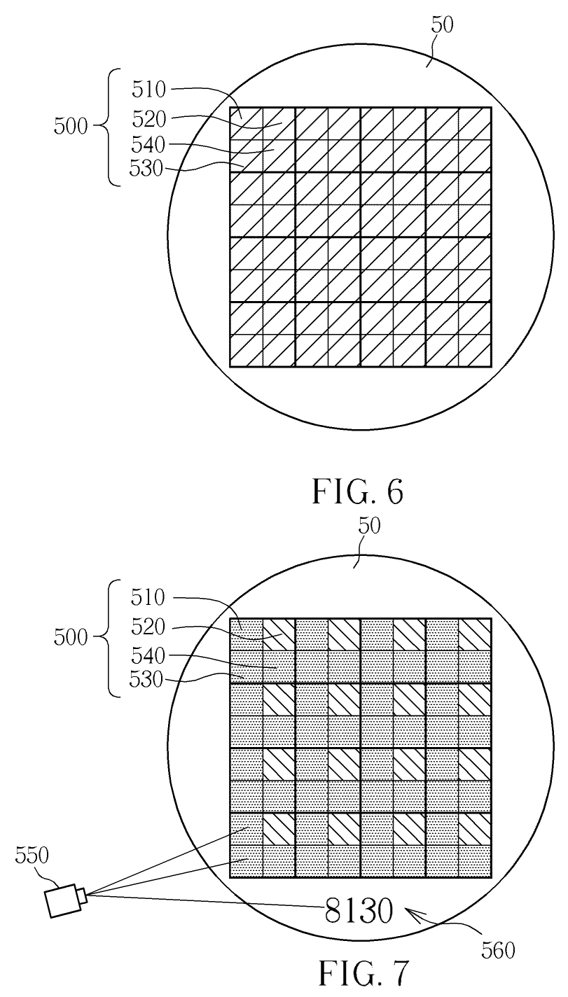

During the fabrication of the substrate 50, as shown in FIG. 6, a first wafer process is performed on the substrate 50 to construct preliminary circuit layout structures. The first wafer process may be various conventional semiconductor processes or testing processes, such as an ion implantation procedure, a thickness measurement, a defect review, a lithographic procedure, a deposition procedure, an etching procedure, a cleaning procedure, a CMP procedure or the combination thereof.

After the first wafer process, an apparatus is used to perform a wafer procedure process and a die destruction process. In the die destruction process, as shown in FIG. 7, simultaneously to completely destroy the die(s) of the first chip manufacturer or of the second chip manufacturer. For instance, in the wafer to be delivered to the second chip manufacturer, the dies other than the second die 520 need to be completely destroyed. Or, part of the first die 510, the third die 530 and the forth die 540 or the entire die needs to be destroyed. Such apparatus may be a measuring device, such as CD SEM or a KLA defect scanning device . . . etc. The destructive energy source used in the die destruction process may be (additionally) installed therein. In one embodiment of the present invention, the wafer procedure process and the die destruction process are carried out in the same device. In another embodiment of the present invention, the wafer procedure process and the die destruction process are carried out in different devices. The device may be installed with the destructive energy source as long as it can identify different dies.

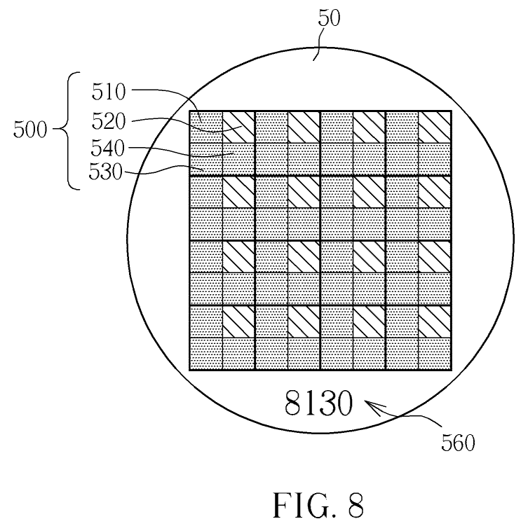

After the die destruction process, as shown in FIG. 8, a second wafer process is performed on the substrate 50 to finish the second die 520. The second wafer process may be various conventional semiconductor processes or testing processes, such as a thickness measurement, a defect review, a defect distribution map, a lithographic procedure, a deposition procedure, an etching procedure, a cleaning procedure and a CMP procedure or the combination thereof. After the second wafer process, only the final products of the second die 520 remain on the substrate 50. Now, the entire wafer is ready to be delivered to the second chip manufacturer without worrying about the secret business information being revealed to other chip manufacturers.

On the other hand, if the entire wafer is delivered to the first chip manufacturer, please refer to the previous descriptions, the other irrelevant business secrets in the die(s) other than the first die 510 need to be completely destroyed, for instance to partially destroy the second die 520, the third die 530 and the forth die 540 or the entire dies and to keep the first die 510. In such way, only the final products of the first die 510 still remain on the substrate 50. Now, the entire wafer is ready to be delivered to the first chip manufacturer without worrying about the secret business information being revealed to other chip manufacturers.

In one preferred embodiment of the present invention, if the energy source used in the conventional semiconductor process is not high enough to destroy all the secret information in the irrelevant dies, devices such as laser, X ray, electron beams and the combination thereof may be optionally added as the destructive energy source. In other words, the destructive energy source may be additionally added, such as CD SEM or a KLA defect scanning device . . . etc. Because the exposure energy is not high enough to destroy all the secret information in the irrelevant dies for such apparatus, the additional destructive energy source device is added to destroy all the secret information in the irrelevant dies. The device may be installed with the destructive energy source as long as it can identify different dies.

Because the method of the present invention is compatible with the conventional semiconductor process and employs a destructive energy source to perform a wafer process and simultaneously to destroy the irrelevant business secrets in the wafer in stead of a conventional diamond-blade saw, in such way, the novel method would not waste any useful chips and destroy the irrelevant business secrets in the wafer at the same time by a simple and convenient way to protect the information in the multi-project wafer (MPW) from the irrelevant third party.

Those skilled in the art will readily observe that numerous modifications and alterations of the device and method may be made while retaining the teachings of the invention.

What is claimed is:

1. A method for the protection of the information in a multi-project wafer (MPW), comprising:
providing a substrate comprising a first die and a second die; and
performing a first wafer process on said substrate, said first wafer process comprising:
performing a wafer procedure by using a non-destructive energy source; and
destroying said first die by using a destructive energy source.

2. The method of claim 1, wherein said non-destructive energy source is selected from a group consisting of laser, incoherent light and electron beams.

3. The method of claim 1, wherein said destructive energy source is selected from a group consisting of laser, X ray and electron beams.

4. The method of claim 1, wherein said first wafer process carries out a thickness measurement.

5. The method of claim 1, wherein said first wafer process carries out a defect review.

6. The method of claim 1, wherein said second wafer process is selected from a group consisting of a lithographic procedure, a deposition procedure, an etching procedure, a cleaning procedure and a CMP procedure.

7. The method of claim 1, further comprising:
performing a second wafer process on said substrate to finish said second die.

8. The method of claim 1, wherein said first wafer process is a laser marking procedure.

9. A method for the protection of the information in a multi-project wafer (MPW), comprising:
providing a substrate comprising a first die and a second die;
performing a first wafer process on said substrate;
performing a wafer procedure process and a die destruction process on said substrate by means of an apparatus; and
performing a second wafer process to finish said second die.

10. The method of claim 9, wherein said first wafer process is selected from a group consisting of a thickness measurement, a defect review, a lithographic procedure, a deposition procedure, an etching procedure, a cleaning procedure and a CMP procedure.

11. The method of claim 9, wherein said second wafer process is selected from a group consisting of a thickness measurement, a defect review, a lithographic procedure, a deposition procedure, an etching procedure, a cleaning procedure and a CMP procedure.

12. The method of claim 9, wherein said wafer procedure process and said die destruction process are carried out in the same apparatus.

13. The method of claim 9, wherein said wafer procedure process and said die destruction process are carried out in different apparatuses.

14. A method for the protection of the information in a multi-project wafer (MPW), comprising:
providing a substrate comprising a first die and a second die; and
performing a first wafer process on said substrate, said first wafer process comprising:
performing a wafer procedure by using a non-destructive energy source; and
destroying part of said first die by using a destructive energy source.

15. The method of claim 14, wherein destroying part of said first die comprising destroying a bonding pad.

16. The method of claim 14, wherein destroying part of said first die comprising destroying a test key pad.
